(19) United States
(12) Patent Application Publication
(10) Pub. No.: US 2025/0246457 A1
(43) Pub. Date: Jul. 31, 2025

(54) PEELING APPARATUS AND PEELING METHOD

(71) Applicant: DISCO CORPORATION, Tokyo (JP)

(72) Inventor: Fumiaki ITO, Tokyo (JP)

(73) Assignee: DISCO CORPORATION, Tokyo (JP)

(21) Appl. No.: 19/034,980

(22) Filed: Jan. 23, 2025

(30) Foreign Application Priority Data
Jan. 31, 2024 (JP) 2024-012377
Aug. 29, 2024 (JP) 2024-147142
Oct. 24, 2024 (JP) 2024-187044

(51) Int. Cl. H01L 21/67; G01L 5/00; H01L 21/683

(52) U.S. Cl. CPC H01L 21/67132; G01L 5/0085; G01L 5/009; H01L 21/6836; H01L 2221/68386

(57) ABSTRACT

A peeling apparatus to peel a protective member from a first surface of a plate-formed workpiece includes a holder table having a holder surface to hold a second surface of the workpiece and a peeling assembly to peel the protective member from the workpiece held on the holder table. The peeling assembly includes a gripping unit to grip the protective member, a horizontal movement assembly to move the gripping unit and the holder table relatively in a horizontal direction, a separating assembly to separate the gripping unit gripping the protective member from the holder table, an interior angle setting unit to set an interior angle between the protective member adhered to the first surface of the workpiece and the protective member being peeled, and a controller to maintain the interior angle at an angle set by the interior angle setting unit while the protective member is being peeled.

### CROSS REFERENCE TO RELATED APPLICATION

This application is based upon and claims the benefit of priority from the prior Japanese Patent Applications No. 2024-012377 filed on Jan. 31, 2024; No. 2024-147142 filed on Aug. 29, 2024; and No. 2024-187044 filed on Oct. 24, 2024; the entire contents of which are incorporated herein by reference.

### FIELD

The present disclosure relates to a peeling apparatus and a peeling method.

### BACKGROUND

Japanese Patent Laid-Open Publication No. 2021-132179 discloses a peeling apparatus configured to peel a protective tape adhered to a wafer therefrom. In the peeling apparatus, once a peeler sheet is adhered to an outer periphery of the protective tape, a gripping unit may grip the peeler sheet. Thereafter, the gripping unit and a holder table to hold the wafer may be relatively moved in a horizontal direction, and the protective tape may be turned to bend and peeled from the wafer.

### SUMMARY

However, while the protective tape is being peeled in the peeling apparatus described above, a bending angle of the protective tape may change, thereby causing the wafer to crack or glue of the protective tape to remain unremoved on the wafer.

In view of these problems, the present disclosure is directed to providing a peeling apparatus and a peeling apparatus, by which a plate-formed workpiece may prevent cracking as a protective member is peeled therefrom, or by which the plate-formed workpiece may prevent glue from adhering thereto.

According to an aspect of the present disclosure, a peeling apparatus, configured to peel a protective member protecting a first surface on one side of a plate-formed workpiece from the first surface, includes a holder table having a holder surface configured to hold a second surface of the plate-formed workpiece on the other side opposite to the first side, and a peeling assembly configured to peel the protective member covering the first surface of the plate-formed workpiece held on the holder table. The peeling assembly includes a gripping unit configured to grip the protective member, a horizontal movement assembly configured to move the gripping unit and the holder table relatively to each other linearly in a horizontal direction, a separating assembly configured to separate the gripping unit gripping the protective member from the holder table, an interior angle setting unit configured to set an interior angle between the protective member adhered to the first surface of the plate-formed workpiece and the protective member being peeled, and a controller configured to maintain the interior angle at an angle set by the interior angle setting unit while the protective member is being peeled.

According to another aspect of the present disclosure, a peeling method for peeling a protective member protecting a first surface on one side of a plate-formed workpiece from the first surface includes a holding process to hold a second surface of the plate-formed workpiece on the other side opposite to the first side, a gripping process to grip the protective member by a gripping unit, and a peeling process to peel the protective member by moving the gripping unit and the holder table relatively to each other linearly in a horizontal direction and separating the gripping unit gripping the protective member from the holder table while maintaining an interior angle between the protective member adhered to the first surface of the plate-formed workpiece and the protective member being peeled from the first surface of the plate-formed workpiece at a preset angle.

According to the present disclosure, the interior angle between the protective member adhered to the plate-formed workpiece and the protective member being peeled may be controlled by the controller to maintain an angle set by the interior angle setting unit. Thereby, the plate-formed workpiece may be prevented from cracking or adherence of glue thereon.

### BRIEF DESCRIPTION OF THE DRAWINGS

FIG. 1 is a schematic perspective view of a peeling apparatus according to a first embodiment of the present disclosure.

FIG. 2 is a schematic cross-sectional partial view of the peeling apparatus according to the first embodiment of the present disclosure.

FIG. 3 is a schematic cross-sectional partial view of a peeling apparatus according to a second embodiment of the present disclosure.

FIG. 4 is a schematic cross-sectional partial view of a peeling apparatus according to a third embodiment of the present disclosure.

FIG. 5 is a schematic cross-sectional partial view of a peeling apparatus according to a fourth embodiment of the present disclosure.

FIG. 6 is a schematic cross-sectional partial view of a peeling apparatus according to a fifth embodiment of the present disclosure.

FIG. 7 is a plan view to illustrate locations of load sensors and a horizontal load detecting unit according to the fifth embodiment of the present disclosure.

FIG. 8 is a graph illustrating a relationship between tensile load and an interior angle.

FIG. 9 is a schematic cross-sectional partial view of a peeling apparatus according to a sixth embodiment of the present disclosure.

FIG. 10 is a schematic cross-sectional partial view of a peeling apparatus according to a seventh embodiment of the present disclosure.

FIG. 11 is a schematic cross-sectional partial view of a peeling apparatus according to an eighth embodiment of the present disclosure.

### DESCRIPTION OF EMBODIMENTS

### First Embodiment

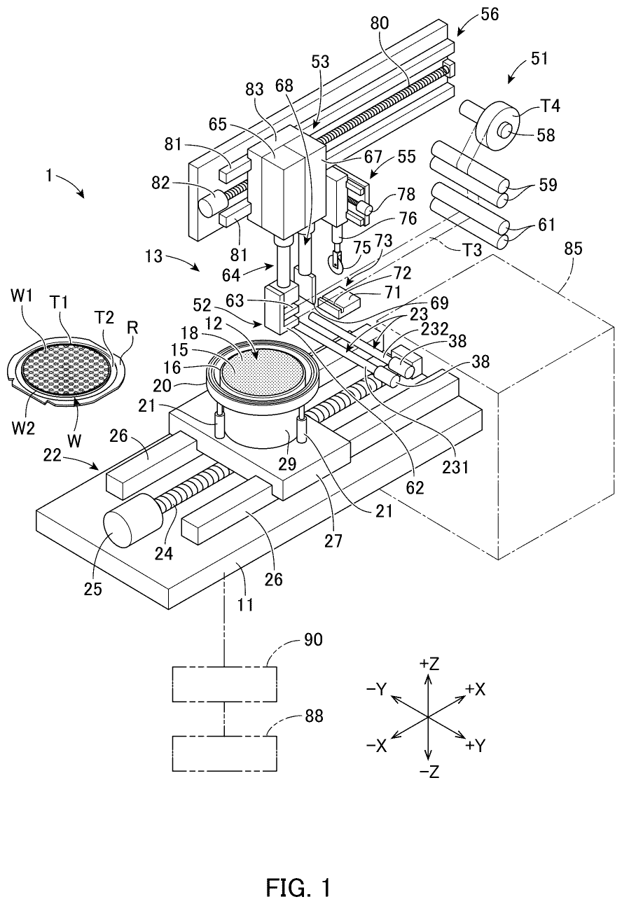

Hereinbelow, with reference to the accompanying drawings, a peeling apparatus according to a first embodiment of the present disclosure will be described. FIG. 1 is a schematic perspective view of the peeling apparatus according to the first embodiment of the present disclosure.

X-axis direction, Y-axis direction, and Z-axis direction shown in each of the drawings are orthogonal to one another. The X-axis direction and the Y-axis direction are horizontal directions, and the Z-axis direction is an up-down direction (vertical direction).

A peeling apparatus 1 shown in FIG. 1 is an example of an apparatus capable of peeling a protective tape T1 (protective member), which protects a surface (first surface) W1 on one side of a plate-formed workpiece W, from the surface W1 on the one side.

The plate-formed workpiece W shown in FIG. 1 is a semiconductor wafer, of which base material is a silicon, having a circular exterior shape. The surface W1 on the one side of the plate-formed workpiece W is partitioned in grid with a plurality of divider lines intersecting orthogonally with one another, and in each of the partitioned sections, a device such as an IC is formed. To the surface W1 on the one side of the plate-formed workpiece W, a protective tape T1 is adhered to cover the surface W1 entirely. The protective tape T1 may be composed of a tape including, for example, a base layer made of resin (for example, polyolefin resin) having a certain degree of flexibility and an adhesive layer (glue layer) formed on the base layer. Optionally, the plate-formed workpiece W may be composed of gallium arsenide, sapphire, ceramics, resin, gallium nitride, or silicon carbide, etc., and the protective tape T1 may be composed of other protective member than the tape described above. The protective member may be, for example, cured liquid resin. Moreover, bumps may be formed in each of the partitioned sections.

To a surface (second surface) W2 on the other side of the plate-formed workpiece W (a downward surface in FIG. 1) opposite to the surface W1 on the one side, a dicing tape T2 with a glue layer having a diameter larger than the plate-formed workpiece W is adhered. An outer periphery of the glue layer of the dicing tape T2 is adhered not only to the surface W2 of the plate-formed workpiece W but also to an annular frame R; thereby, the plate-formed workpiece W is supported by the annular frame R through the dicing tape T2 and is enabled to be handled through the annular frame R.

The peeling apparatus 1 includes a base 11, a holder table 12 located above the base 11 to hold the surface W2 on the other side of the plate-formed workpiece W, and a peeling assembly 13 for peel the protective tape T1 from the plate-formed workpiece W held on the holder table 12. The base 11 is provided in a form of a rectangular parallelepiped elongated in the X-axis direction.

The holder table 12 includes a suctioning part 15 made of, for example, a porous member for suctioning the plate-formed workpiece W and a frame 16. The suctioning part 15 is continuous with a suctioning source such as a vacuuming device, which is not shown, and a suctioning force generated by the suctioning source may be conveyed to a holder surface 18, which is an exposed flat surface of the suctioning part 15. Accordingly, the surface W2 on the other side of the plate-formed workpiece W may be suctioned and held against the holder surface 18 of the holder table 12, with the dicing tape T2 intervening there-between.

The holder table 12 is surrounded by a frame-fixing part 20 that fixes the annular frame R thereon. The frame-fixing part 20 has an annular exterior shape in a plan view, and with the annular frame R placed thereon, the frame-fixing part 20 may suction and fix the annular frame R there-onto by the suctioning force produced by the suctioning source, which is not shown. Moreover, the frame-fixing part 20 is movable up and down in the Z-axis direction (vertical direction) with piston assemblies 21 that are arranged evenly along a circumferential direction. Optionally, in place of the frame-fixing part 20, mechanical clamps that may open or close by springs and the like may be arranged around the holder table 12.

The peeling assembly 13 includes a first horizontal movement assembly 22, which is located above the base 11 and is configured to move the holder table 12 to reciprocate along the X-axis direction, and two rollers 23 that form a gripping unit. The two rollers 23 are located at the same position in the Z-axis direction (height direction) and extend in the Y-axis direction.

The first horizontal movement assembly 22 includes a ball screw 24 arranged on the base 11, a motor 25 connected to one end of the ball screw 24, a pair of guide rails 26 extending in parallel to the ball screw 24, and a movable member 27 which is movable in the X-axis direction. On an upper surface of the movable member 27, the holder table 12 is located through a supporting portion 29. A lower surface of the movable member 27 is in contact slidably with a pair of guide rails 26, and the ball screw 24 is screwed to a nut which is not shown but is arranged on the lower surface of the movable member 27. By driving of the motor 25, the ball screw 24 rotates, and the holder table 12 along with the movable member 27 moves in the X-axis direction along the guide rails 26.

The first horizontal movement assembly 22 moves the two rollers 23 and the holder table 12 relatively in the X-axis direction (horizontal direction), which is parallel to the holder surface 18. Thereby, the two rollers 23 are moved linearly in a direction from an outer periphery of the holder surface 18 toward and passing over a center of the holder surface 18, and away from the center of the holder surface 18.

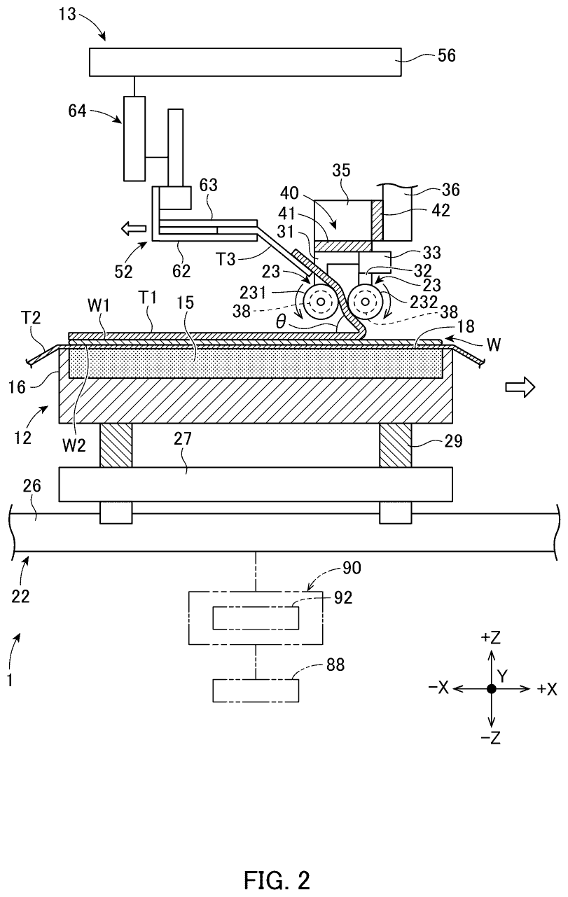

FIG. 2 is a schematic partial view of the peeling apparatus according to the first embodiment of the present disclosure. As shown in FIG. 2, the two rollers 23 extend in the Y- axis direction and align in the X-axis direction; one of the two rollers 23 is a fixed roller 231, and the other of the two rollers 23 is a movable roller 232. According to the present embodiment, the fixed roller 231 is located on a −X side, and the movable roller 232 is located on a +X side.

The fixed roller 231 is supported by an angled fixed frame 31, and the movable roller 232 is supported by a movable frame 32 extending in the vertical direction. The movable frame 32 is connected to a gripping cylinder 33 which composes a gripping unit. The gripping cylinder 33 may be composed of, for example, an air cylinder and move the movable frame 32 and the movable roller 232 to reciprocate in the X-axis direction. The fixed frame 31 and the fixed roller 231 are relatively immovable to the gripping cylinder 33. By driving of the gripping cylinder 33, the protective tape T1 and a peeler tape T3, which will be described further below, may be nipped between the fixed roller 231 and the movable roller 232 and gripped thereat.

The fixed frame 31 and the gripping cylinder 33 are supported by a connecting body 35 connected above, and the connecting body 35 is supported by a supporting pole 36 through a sideward surface thereof on the +X side.

The peeling assembly 13 further includes a rotation driving unit 38 composing the separating assembly. The rotation driving unit 38 may be composed of, for example, motors provided to the two rollers 23, respectively, and may rotate the two rollers 23 relatively. Thereby, a lifting force may be applied to the protective tape T1, and the like, nipped and gripped by the two rollers 23, and the two rollers 23 may separate the protective tape T1 from the holder table 12.

The peeling assembly 13 further includes a tensile load measuring unit 40 for measuring a tensile load acting on the protective tape T1 intervening between the two rollers 23 and the holder surface 18. The tensile load measuring unit 40 includes a vertical load detecting unit 41 and a horizontal load detecting unit 42.

The vertical load detecting unit 41 is located at a connecting portion between the fixed frame 31 and the gripping cylinder 33, and the connecting body 35 to be flanked by these members from both sides in the Z-axis direction. The vertical load detecting unit 41 detects a vertical tensile load acting in the vertical direction (hereinbelow referred to as “vertical load” in the present embodiment) on the protective tape T1 gripped by the two rollers 23. The horizontal load detecting unit 42 is located at a connecting portion between the connecting body 35 and the supporting pole 36 to be flanked by these members from both side in the X-axis direction. The horizontal load detecting unit 42 detects a horizontal tensile load acting in the horizontal direction (hereinbelow referred to as “horizontal load” in the present embodiment) on the protective tape T1 gripped by the two rollers 23.

The vertical load detecting unit 41 and the horizontal load detecting unit 42 may be, for example, composed of piezoelectric devices. The piezoelectric devices may each be formed of a material such as, for example, barium titanate (BaTiO3), lead zirconate titanate (PZT), lithium niobate (LiNbO3), or lithium tantalate (LiTaO3), in a flat-leafy or columnar shape and may convert a received load into a voltage signal and output the signal to a controller 90, which will be described further below.

Referring back to FIG. 1, the peeling assembly 13 includes a peeler tape supplying unit 51 for drawing the peeler tape T3 out from a tape roll T4, which is the peeler tape T3 in a rolled form, and supplying the peeler tape T3 to the holder table 12. Moreover, the peeling assembly 13 includes a clamp 52 for gripping the peeler tape T3 adhered to the protective tape T1, a peeler tape attaching unit 53 for adhering the peeler tape T3 onto an outer periphery of the protective tape T1, and a tape cutting unit 55 for cutting the peeler tape T3 to a predetermined length. Furthermore, the peeling assembly 13 includes a second horizontal movement assembly 56 for moving the peeler tape attaching unit 53 and the clamp 52 in the X-axis direction. The peeler tape supplying unit 51, the clamp 52, the peeler tape attaching unit 53, the tape cutting unit 55, and the second horizontal movement assembly 56 are arranged above a movable path of the holder table 12.

The peeler tape supplying unit 51 includes a roll cylinder 58 on which the tape roll T4 is mounted, a pair of guide rollers 59 for guiding the peeler tape T3 drawn out from the tape roll T4 downward, and a pair of feed rollers 61 located below the pair of guide rollers 59. To the roll cylinder 58, back tension is applied by a rotating device, which is not shown, to adjust the tension in the peeler tape T3 drawn out from the tape roll T4 so that the peeler tape T3 may not loosen. The pair of guide rollers 59 nip and turn the peeler tape T3 backward, while applying the tension to the peeler tape T3, and guide the peeler tape T3 toward the pair of feed rollers 61, and the pair of feed rollers 61 direct the peeler tape T3 toward the clamp 52.

The peeler tape T3 may be, for example, a heat sealer in a two-layered form having an adhesive layer to be heated and adhered to the outer periphery of the protective tape T1 and a base material. The base material may be made of resin such as, for example, polyethylene terephthalate. The adhesive layer may be formed of thermosetting resin such as, for example, epoxy resin. An adhesive force of the peeler tape T3 to the protective tape T1 is set to be stronger than an adhesive force of the protective tape T1 to the plate-formed workpiece W. The peeler tape T3 is rolled in an arrangement such that the adhesive layer is located inward (downward in an extended state) to form the tape roll T4. The peeler tape T3 may not necessarily be limited to the heat sealer.

The clamp 52 is composed of a fixed claw 62 and a movable claw 63, which form a pair of gripping claws. The fixed claw 62 is provided in an approximate form of an L in a sideward view. The movable claw 63 is located to face the fixed claw 62 in the Z-axis direction and is movable to separate from or approach the fixed claw 62. The clamp 52 may grip an end of the peeler tape T3 between the fixed claw 62 and the movable claw 63 by moving the movable claw 63 approach the fixed claw 62. On the other hand, the clamp 52 may release the end of the peeler tape T3 by moving the movable claw 63 to separate from the fixed claw 62.

The clamp 52 is movable up and down by a clamp lift/lower assembly 64 being an electric actuator composed of, for example, a ball screw assembly and the like. The clamp lift/lower assembly 64 is mounted on the base 65, and the base 65 is fixed to a sideward surface of a movable plate 83, which will be described further below, of the second horizontal movement assembly 56. With the clamp lift/lower assembly 64, by adjusting the position of the clamp 52 gripping the peeler tape T3 in the Z-axis direction, the peeler tape T3 may be located at a position above the protective tape T1 on the plate-formed workpiece W held on the holder table 12 preferable to be adhered to the protective tape T1.

The peeler tape attaching unit 53 is located between the pair of feed rollers 61 and the clamp 52. The peeler tape attaching unit 53 includes a supporting base 67 fixed to a sideward surface of the movable plate 83, which will be described further below, of the second horizontal movement assembly 56, a pressing plate lift/lower assembly 68 composed of an air cylinder and the like supported by the supporting base 67, and a pressing plate 69 vertically movable by the pressing plate lift/lower assembly 68.

The pressing plate 69 is provided with a heater, which is not shown but may generate heat by an electric current applied thereto. As the pressing plate lift/lower assembly 68 lowers the pressing plate 69 and urges the peeler tape T3 against the outer periphery of the protective tape T1 through the pressing plate 69, the heater heats the pressing plate 69, and thereby the peeler tape T3 is partially thermally fused to the protective tape T1. As such, the peeler tape T3 is attached to the protective tape T1 preferably.

The tape cutting unit 55 is located between the pair of feed rollers 61 and the peeler tape attaching unit 53. The tape cutting unit 55 includes a placement surface 71, on which the peeler tape T3 is placed with the adhesive layer facing thereto (downward), a placement base 73 including a groove 72 that traverses the placement surface 71 in a widthwise direction (Y-axis direction) of the peeler tape T3, and a cutter 75 movable in the groove 72 along an extending direction of the groove 72. Moreover, the tape cutting unit 55 includes a cutter lift/lower unit 76, which is composed of an air cylinder and the like and may lift or lower the cutter 75 with respect to the placement surface 71, and a cutter moving unit 78 being a ball screw assembly, which supports the cutter 75 through the cutter lift/lower unit 76 and may move the cutter 75 in the extending direction (Y-axis direction) of the groove 72.

The second horizontal movement assembly 56 includes a ball screw 80 having an axis in the X-axis direction, a pair of guide rails 81 extending in parallel to the ball screw 80, and a motor 82 connected to the ball screw 80 to rotate the ball screw 80. Moreover, the second horizontal movement assembly 56 includes the movable plate 83, in which a nut is screwed to the ball screw 80 and one side of which is slidably in contact with the guide rails 81. In the second horizontal movement assembly 56, as the motor 82 rotates the ball screw 80, the movable plate 83 being guided by the guide rails 81 reciprocates in the X-axis direction, and the peeler tape attaching unit 53 and the clamp 52 mounted on the movable plate 83 also reciprocate in the X-axis direction.

At a position below and on the +X side of the second horizontal movement assembly 56, a collecting box 85, in which the protective tape T1 gripped by the clamp 52 and peeled off from the plate-formed workpiece W may be dropped to be collected, is provided.

The peeling apparatus 1 further includes an interior angle setting unit 88 and the controller 90 to control the components in the apparatus. The interior angle setting unit 88 has a function to set an interior angle θ (see FIG. 2) between a part of the protective tape T1 attached to the surface W1 on the one side of the plate-formed workpiece W and another part of the protective tape T1 peeled off from the surface W1 while the protective tape T1 is being peeled. The interior angle setting unit 88 may, as long as the function described above is provided therewith, employ one of any various configurations and may be, for example, provided in a form of an input apparatus that may be operated by a user to input an interior angle θ (e.g., 10 degrees or 30 degrees) to the controller 90. For another example, the interior angle setting unit 88 may be provided in a form of a computer that may input an interior angle θ, which is obtained based on a peeling condition input by a user with reference to a database, programs, and/or tables that are prepared in advance, to the controller 90. The peeling condition may include, for example, a thickness of the adhesive layer of the protective tape T1, a thickness of the plate-formed workpiece W, and an adhesive force of the protective tape T1. Optionally, the interior angle setting unit 88 may be configured to perform the function described above in the same device forming the controller 90.

The controller 90 is composed of, not only a processor to execute various processes, but also a storage unit (memory) that stores parameters and programs. The storage unit of the controller 90 may store controlling programs including, for example, programs to control acts of the peeling assembly 13 including the holder table 12, the first horizontal movement assembly 22, and the rotation driving unit 38. For example, the controller 90 may control the first horizontal movement assembly 22 and the rotation driving unit 38, based on the stored programs and the detection signals output from the tensile load measuring unit 40, to maintain the interior angle θ (angle) as set by the interior angle setting unit 88 when the protective tape T1 is being peeled.

For example, the controller 90 includes a ratio calculating unit 92 (see FIG. 2), which may calculate an optimal value for a ratio between the horizontal load and the vertical load for forming the interior angle θ as set by the interior angle setting unit 88 with the protective tape T1. Optionally, the optimal value may be an allowable range of the ratios. In the following description concerning the acts of the peeling apparatus 1, unless a subject of the controlling acts is specified, it is considered that the acts are controlled by controlling signals output from the controller 90.

Next, how the protective tape T1 is peeled from the plate-formed workpiece W (peeling method) using the peeling apparatus 1 according to the embodiment of the present disclosure as shown in FIG. 1 will be described.

In preparation for peeling the protective tape T1 from the plate-formed workpiece W, the interior angle θ to be the optimal value is set through the interior angle setting unit 88 in advance and stored in the controller 90. The interior angle θ is an angle, by which the load to be produced by the protective tape T1 being peeled to act on the plate-formed workpiece W may be minimized and the plate-formed workpiece W may be prevented from cracking or adherence of the glue.

Moreover, in preparation for peeling the protective tape T1, the ratio calculating unit 92 in the controller 90 executes a calculating process, by which peeling of the protective tape T1 is performed under a condition such that the interior angle θ is controlled to be the interior angle θ of the optimal value set by the interior angle setting unit 88. In the calculating process, for example, a load corresponding to the interior angle θ of the optimal value set by the interior angle setting unit 88 may be set provisionally, and a ratio between a horizonal load, which is a directional component of the load in the horizontal direction, and a vertical load, which is a directional component of the load in the vertical direction, may be calculated. The calculated ratio is stored in the controller 90 as a ratio that is the optimal value for the protective member T1 to form the interior angle θ during the peeling of the protective tape T1.

First, a holding process is performed. In the holding process, the plate-formed workpiece W unified with the annular frame R is mounted on the holder surface 18 of the holder table 12 with the protective tape T1 facing upward, and the annular frame R is mounted on the frame-fixing part 20 arranged on the outer periphery of the holder table 12. Next, as the suctioning source which is not shown is activated, the plate-formed workpiece W is suctioned and held against the holder surface 18, and the annular frame R is suctioned and fixed to the frame-fixing part 20. Thereafter, the annular frame R is lowered to a position lower than the holder surface 18.

In this state, a gripping process is performed. In the gripping process, the peeler tape T3 is fed by the pair of guide rollers 59 from the tape roll T to the clamp 52. The peeler tape T3 is placed on the placement surface 71 of the placement base 73 in the tape cutting unit 55 with the adhesive layer (inner side) facing the placement surface 71, one end of the peeler tape T3 is located on an upper surface of the fixed claw 62 of the clamp 52, and thereafter the movable claw 63 approaches the fixed claw 62, and the clamp 52 grips the one end of the peeler tape T3. Next, the clamp 52 gripping the peeler tape T3 is moved by the second horizontal movement assembly 56 in the −X direction and pulls the peeler tape T3 in the −X direction. At this point, the pressing plate 69 in the peeler tape attaching unit 53 and the cutter 75 in the tape cutting unit 55 stand by above the peeler tape T3, and the two rollers 23 stands by below the peeler tape T3.

In this state, the holder table 12 moves in the +X direction and locates the outer peripheral portion of the protective tape T1 at a position straight below the peeler tape attaching unit 53. Next, the pressing plate 69 heated by the heater, which is not shown, descends and urges the peeler tape T3 from above by a lower end thereof against the outer peripheral portion of the protective tape T1 to thermally fuse the adhesive layer of the peeler tape T3 to the protective tape T1. The descending pressing plate 69 passes through the clearance between the two rollers 23, and the peeler tape T3 is thermally fused to the protective tape T1 at a position below the two rollers 23.

After the peeler tape T3 is thermally fused, the cutter 75 is moved by the cutter moving unit 78 to a position on one end of the groove 72 in the placement base 73 exposed from one sideward edge of the peeler tape T3. Moreover, the cutter 75 is lowered by the cutter lift/lower unit 76 to a position where a lower end of the cutter 75 enters the groove 72. Next, the cutter 75 moves along the extending direction of the groove 72 in the −Y direction, thereby cutting the peeler tape T3 off. After the cutter 75 cuts the peeler tape T3 off, the cutter 75 and the pressing plate 69 ascend in the +Z direction to withdraw from the peeler tape T3.

Thereafter, by driving the gripping cylinder 33 as shown in FIG. 2, the two rollers 23 are moved to approach each other. Thereby, the peeler tape T3 thermally fused to the protective tape T1 is gripped at one end by the clamp 52 and at a portion between the one end and the part being thermally fused to the protective tape T1 by the two rollers 23.

In this state, a peeling process is performed. In the peeling process, the holder table 12 is moved by the first horizontal movement assembly 22 in the +X direction with respect to the two rollers 23, of which position in the X-axis direction is fixed, so that the two rollers 23 may move relatively from an end of the plate-formed workpiece W on the +X side toward the other end on the −X side. Thereby, a portion of the protective tape T1 in proximity to the thermally fused portion of the peeler tape T3 is pulled obliquely upward (in the +Z direction and the −X direction), and the protective tape T1 starts being peeled from the plate-formed workpiece W from the end of the protective tape T1 on the +X side. As the protective tape T1 is being peeled, the clamp 52 is moved by the second horizontal movement assembly 56 in the −X direction. Moreover, as the protective tape T1 is being peeled, the rotation driving unit 38 is driven to rotate the two rollers 23 relatively to each other, and the peeler tape T3 and the protective tape T1 are rolled up in this given sequence to peel the protective tape T1 off. While the two rollers 23 roll up and peel the protective tape T1, the protective tape T1 is turned to bend so that the interior angle θ between the part of the protective tape T1 adhered to the surface W1 on the one side of the plate-formed workpiece W and the part of the protective tape T1 peeled from the plate-formed workpiece W forms an acute angle.

As the protective tape T1 is being peeled from the plate-formed workpiece W, a tensile load caused by the act of rolling up of the rotation driving unit 38 and the movement of the holder table 12 in the +X direction acts on the protective tape T1, and the tensile load is measured by the tensile load measuring unit 40. More specifically, the vertical load detecting unit 41 in the tensile load measuring unit 40 detects a vertical load acting on the protective tape T1 gripped by the two rollers 23. Moreover, the horizontal load detecting unit 42 detects a horizontal load acting on the protective tape T1 gripped by the two rollers 23. The vertical and horizontal load detecting units 41, 42 detect the tensile loads periodically at predetermined intervals and output the detection signals corresponding to the vertical load and the horizontal load to the controller 90.

While the protective tape T1 is being peeled, the controller 90 controls the first horizontal movement assembly 22 and the rotation driving unit 38 to maintain the interior angle θ to be interior angle θ of the optimal value set by the interior angle setting unit 88. The controller 90 may control the first horizontal movement assembly 22 and the rotation driving unit 38 by, for example, inputting the detection signals that correspond to the horizontal load and the vertical load output from the vertical and horizontal load detecting units 41, 42 and calculating a ratio between the vertical load detected by the vertical load detecting unit 41 and the horizontal load detected by the horizontal load detecting unit 42. Moreover, the controller 90 may compare the calculated ratio with the ratio of the optimal value calculated and stored by the ratio calculating unit 92. Based on the comparison, the controller 90 may adjust a speed to move the holder table 12 through the first horizontal movement assembly 22 and/or adjust a rotation speed to rotate the two rollers 23 through the rotation driving unit 38. Under this control, the ratio calculated by the controller 90 may be led to equal or approach the ratio of the optimal value calculated by the ratio calculating unit 92, and the actual interior angle θ of the protective tape T1 being peeled may be led to equal or approach the interior angle θ of the optimal value set by the interior angle setting unit 88.

Once the protective tape T1 is peeled completely from the surface W1 on the one side of the plate-formed workpiece W, the clamp 52 gripping the peeler tape T3 adhered to the peeled protective tape T1 moves to a position above the collecting box 85 (see FIG. 1). There, the clamp 52 releases the peeler tape T3 and let the protective tape T1 and the peeler tape T3 fall in the collecting box 85.

According to the first embodiment described above, under the control of the controller 90, the interior angle θ between the protective tape T1 adhered to the surface W1 on the one side of the plate-formed workpiece W and the protective tape T1 peeled from the surface W1 may be maintained at the interior angle θ of the optimal value. Thereby, the bending angle of the protective tape T1 during the peeling may be prevented from changing, and the plate-formed workpiece W may be prevented from cracking or from adherence of the glue thereon. Next, embodiments of the present disclosure other than the above-described

embodiment will be described. In the description below, components identical or substantially equal to those in the embodiment(s) described earlier may be referred to by the same reference signs, and detailed description of those may be omitted or simplified.

### Second Embodiment

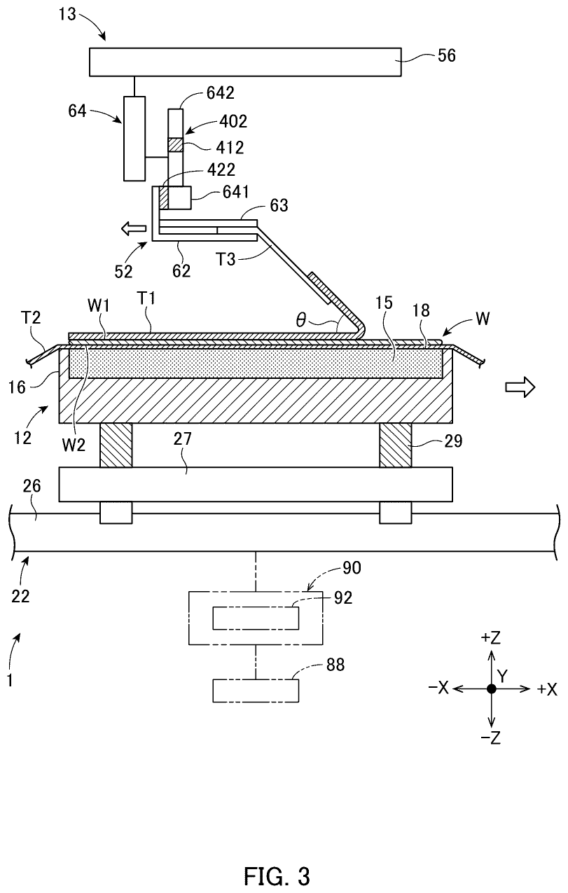

With reference to FIG. 3, a second embodiment of the present disclosure will be described. FIG. 3 is a schematic cross-sectional partial view, similarly to FIG. 2, of the peeling apparatus according to the second embodiment of the present disclosure. As shown in FIG. 3, the second embodiment omits the two rollers 23 and the structure to support the rollers 23 included in the first embodiment. Moreover, in the second embodiment, the gripping unit is composed of the clamp 52, and the separating assembly is composed of the clamp lift/lower assembly 64 that may lift or lower the clamp 52. The clamp 52 may grip the peeler tape T3 forming the outer peripheral portion of the protective tape T1.

In the second embodiment, for peeling the protective tape T1 as shown in FIG. 3 (peeling process), the holder table 12 is moved by the first horizontal movement assembly 22 in the +X direction, and the clamp 52 gripping the peeler tape T3 is moved by driving of the second horizontal movement assembly 56 (horizontal movement assembly) in the −X direction. Thereby, the clamp 52 and the holder table 12 move relatively to each other linearly in the horizontal direction, and the protective tape T1 is pulled obliquely upward (in the +Z direction and the −X direction) and peeled from the plate-formed workpiece W. While the protective tape T1 is being peeled, the position of the clamp 52 in the Z-axis direction is adjusted by driving the clamp lift/lower assembly 64 to move (lift) the clamp 52 in the +Z direction. In the second embodiment, as well as the previous embodiment, while the protective tape T1 is being peeled, the protective tape T1 is turned to bend so that the interior angle θ between the portion of the protective tape T1 adhered to the surface W1 on the one side of the plate-formed workpiece W and the portion of the protective tape T1 peeled from the plate-formed workpiece W forms an acute angle.

According to the second embodiment, the tensile load to pull to peel the protective tape T1 acts on the members that support the clamp 52. Therefore, a tensile load measuring unit 402 in the second embodiment differs from the tensile load measuring unit 40 in the first embodiment in the location and the measuring object thereof. In the second embodiment, a vertical load detecting unit 412 and a horizontal load detecting unit 422 in the tensile load measuring unit 402 are provided to the structure or the members that support the clamp 52.

In particular, the horizontal load detecting unit 422 is located at a connecting portion between a sideward surface of an upper portion of the fixed claw 62 of the clamp 52 on the +X side and a connecting body 641 facing toward the sideward surface to be flanked by these members from both side in the X-axis direction. The vertical load detecting unit 412 is located to form a part of a piston rod 642 in the clamp lift/lower assembly 64 that supports the connecting body 641, at an intermediate position in an extending direction (Z-axis direction) of the piston rod 642. As such, the vertical load detecting unit 412 may detect the vertical load acting on the protective tape T1 gripped by the clamp 52, and the horizontal load detecting unit 422 may detect the horizontal load acting on the protective tape T1 gripped by the clamp 52.

In the second embodiment, the tensile load acting on the protective tape T1 being peeled is detected by the vertical and horizontal load detecting units 412, 422 periodically at predetermined intervals and output the detection signals corresponding to the horizontal load and the horizontal load to the controller 90.

While the protective tape T1 is being peeled, the controller 90 controls the first and second horizontal movement assemblies 22, 56 and the clamp lift/lower assembly 64 to maintain the interior angle θ at the optimal value set by the interior angle setting unit 88. The controller 90 may control the first and second horizontal movement assemblies 22, 56 and the clamp lift/lower assembly 64 by, for example, inputting the detection signals that correspond to the horizontal load and the vertical load output from the horizontal load and the vertical load output from the vertical and horizontal load detecting units 412, 422 and calculating a ratio between the vertical load detected by the vertical load detecting unit 412 and the horizontal load detected by the horizontal load detecting unit 422. Moreover, the controller 90 may compare the calculated ratio with the ratio of the optimal value calculated and stored by the ratio calculating unit 92. Based on the comparison, the controller 90 may adjust speeds to move the holder table 12 and the clamp 52 through the first and second horizontal movement assemblies 22, 56 and/or adjust a lifting speed of the clamp 52 through the clamp lift/lower assembly 64. Under this control, the ratio calculated by the controller 90 may be led to equal or approach the ratio of the optimal value calculated by the ratio calculating unit 92, and the actual interior angle θ of the protective tape T1 being peeled may be led to equal or approach the interior angle θ of the optimal value set by the interior angle setting unit 88.

### Third Embodiment

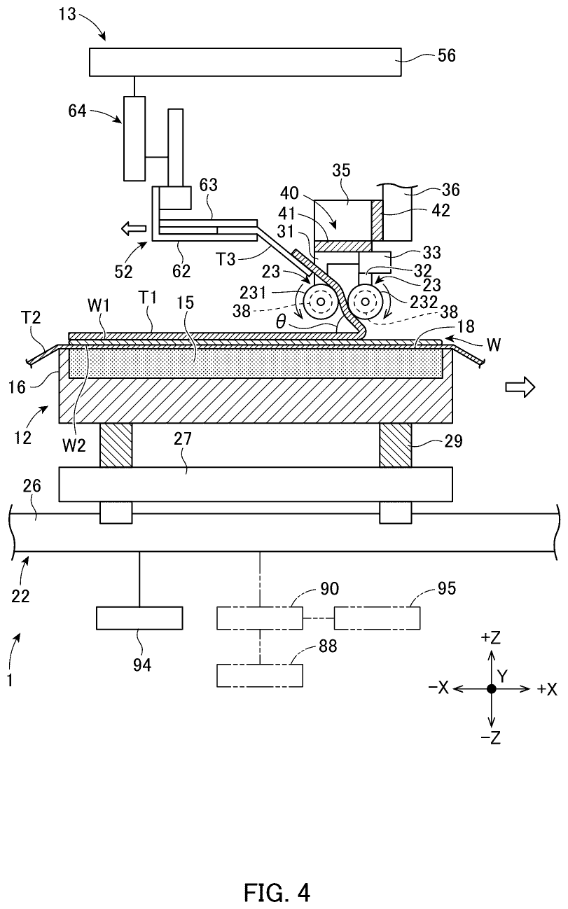

With reference to FIG. 4, a third embodiment of the present disclosure will be described. FIG. 4 is a schematic cross-sectional partial view, similarly to FIG. 2, of the peeling apparatus according to the third embodiment of the present disclosure. As shown in FIG. 4, the third embodiment illustrates a peeling apparatus, which is similar to the peeling apparatus in the first embodiment, further provided with a horizontal position detecting unit 94. Moreover, the third embodiment omits the ratio calculating unit 92 included in the first embodiment but is provided with a data table 95.

The horizontal position detecting unit 94 in the third embodiment may be provided as, for example, a rotary encoder that may detect a number of rotations of the motor 25 (see FIG. 1) in the first horizontal movement assembly 22. The horizontal position detecting unit 94 may output encoder signals indicating the number of rotations of the motor 25 to the controller 90, and the controller 90 may recognize a position of the holder table 12 in the X-axis direction (horizontal direction) based on the encoder signals. As such, relative positions of the two rollers 23 and the holder table 12 in the horizontal direction may be detected by the horizontal position detecting unit 94.

The data table 95 defines and stores rotation speeds of the rotation driving unit 38 corresponding to the relative horizontal positions detectable as above. The data table 95 is a table, in which the rotation speeds of the rotation driving unit 38 are set according to the positions of the holder table 12 in the X-axis direction in order to maintain the interior angle θ while the protective tape T1 is being peeled at the optimized value set by the interior angle setting unit 88. The data table 95 may optionally be stored either in a device separate from the controller 90 or in a storage in the controller 90.

According to the third embodiment, while the protective tape T1 is being peeled (in the peeling process), the controller 90 controls the first horizontal movement assembly 22 to move the holder table 12 in the +X direction at a constant speed. Further, while the protective tape T1 is being peeled, the horizontal position detecting unit 94 detects the positions of the holder table 12 in the X-axis direction. Furthermore, while the protective tape T1 is being peeled, the controller 90 controls the rotation driving unit 38 to maintain the interior angle θ at the optimal value set by the interior angle setting unit 88. The controller 90 may control the rotation driving unit 38 by, for example, setting the rotation speed of the rotation driving unit 38 based on the position of the holder table 12 in the X-axis direction (horizontal direction) detected by the horizontal position detecting unit 94 with reference to the data table 95. As such, the controller 90 may control the rotation driving unit 38 to rotate at the rotation speed set as above and adjust the rotation speed of the two rollers 23. Under this control, the actual interior angle θ of the protective tape T1 while being peeled may be led to equal or approach the interior angle θ of the optimal value set by the interior angle setting unit 88.

### Fourth Embodiment

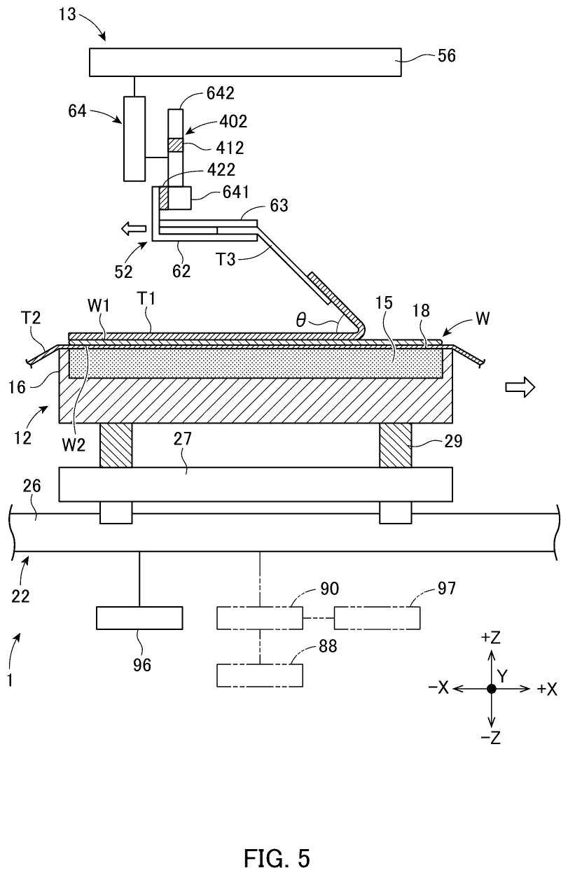

With reference to FIG. 5, a fourth embodiment of the present disclosure will be described. FIG. 5 is a schematic cross-sectional partial view, similarly to FIG. 2, of the peeling apparatus according to the fourth embodiment of the present disclosure. As shown in FIG. 5, the fourth embodiment illustrates a peeling apparatus, which is similar to the peeling apparatus in the second embodiment, further provided with a horizontal position detecting unit 96. Moreover, the fourth embodiment omits the ratio calculating unit 92 included in the second embodiment but is provided with a data table 97.

The horizontal position detecting unit 96 in the fourth embodiment has the same function as the horizontal position detecting unit 94 in the third embodiment and, moreover, a function to recognize a position of the clamp 52 (gripping unit) in the X-axis direction (horizontal direction). Therefore, the horizontal position detecting unit 96 may employ a configuration including a rotary encoder to detect a number of rotations of the motor 82 (see FIG. 1) in the second horizontal movement assembly 56. The horizontal position detecting unit 96 may output encoder signals indicating the number of rotations of the motor 82 to the controller 90, and the controller 90 may recognize a position of the clamp 52 in the X-axis direction (horizontal direction) based on the encoder signals. As such, relative positions of the clamp 52 and the holder table 12 in the horizontal direction may be detected by the horizontal position detecting unit 96.

The data table 97 defines and stores ascending speeds of the clamp lift/lower assembly 64 corresponding to the relative horizontal positions detectable as above. The data table 95 is a table, in which the ascending speeds of the clamp lift/lower assembly 64 are set according to the positions of the clamp 52 and the holder table 12 in the X-axis direction in order to maintain the interior angle θ while the protective tape T1 is being peeled at the optimized interior angle θ set by the interior angle setting unit 88. The data table 97 may optionally be stored either in a device separate from the controller 90 or in a storage in the controller 90.

According to the fourth embodiment, while the protective tape T1 is being peeled (in the peeling process), the controller 90 controls the first horizontal movement assembly 22 to move the holder table 12 in the +X direction at a constant speed and controls the second horizontal movement assembly 56 to move the clamp 52 in the −X direction at a constant speed. As such, under the control of the controller 90, the clamp 52 and the holder table 12 may move relatively to each other linearly in the horizontal direction by the first and second horizontal movement assemblies 22, 56. Further, while the protective tape T1 is being peeled, the horizontal position detecting unit 96 detects the positions of the clamp 52 and the holder table 12 in the X-axis direction. Furthermore, while the protective tape T1 is being peeled, the controller 90 controls the clamp lift/lower assembly 64 to maintain the interior angle θ at the optimal value set by the interior angle setting unit 88. The controller 90 may control the clamp lift/lower assembly 64 by, for example, setting the ascending speed of the clamp 52 through the clamp lift/lower assembly 64 based on the positions of the clamp 52 and the holder table 12 in the X-axis direction (horizontal direction) detected by the horizontal position detecting unit 96 with reference to the data table 97. As such, the position of the clamp 52 in the vertical direction may be adjusted while the protective tape T1 is being peeled, and the actual interior angle θ of the protective tape T1 while being peeled may be led to equal or approach the interior angle θ of the optimal value set by the interior angle setting unit 88.

### Fifth Embodiment

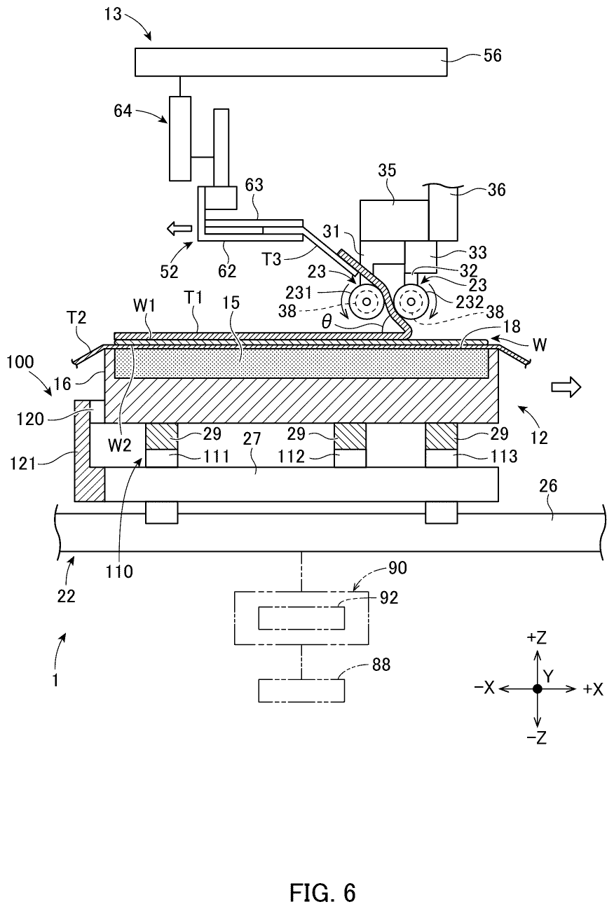

With reference to FIG. 6, a fifth embodiment of the present disclosure will be described. FIG. 6 is a schematic cross-sectional partial view, similarly to FIG. 2, of the peeling apparatus according to the fifth embodiment of the present disclosure. As shown in FIG. 6, the fifth embodiment illustrates a peeling apparatus, which is similar to the peeling apparatus in the first embodiment but is provided with a tensile load measuring unit 100 in place of the tensile load measuring unit 40. In the fifth embodiment, a vertical load detecting unit 110 and a horizontal load detecting unit 120 in the tensile load measuring unit 100 are arranged around the holder table 12.

According to the fifth embodiment, the vertical load detecting unit 110 in the tensile load measuring unit 100 is composed of three load sensors 111-113, which are arranged on three columnar-formed supporting portions 29, respectively. The load sensors 111-113 are each located at a connecting portion between an upper surface (surface toward the +Z side) of the movable member 27 and a lower surface (surface toward the −Z side) of the supporting portion 29 to be flanked by these members from both sides in the Z-axis direction. As such, the vertical load detecting unit 110 (load sensors 1111-113) are located below the holder table 12 to support the holder table 12.

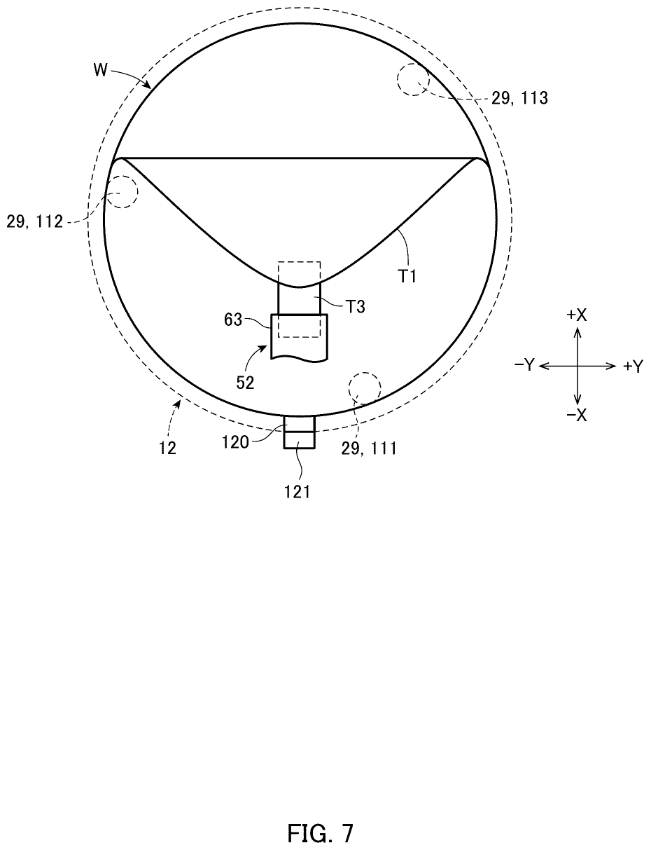

FIG. 7 is a plan view to illustrate the locations of the load sensors 111-113 and the horizontal load detecting unit 120 according to the fifth embodiment of the present disclosure. As shown in FIG. 7, in the view from above, the three supporting portions 29 and the three load sensors 111-113 are arranged at positions toward the outer periphery of the holder table 12 at predetermined angular intervals (every 120 degrees in FIG. 7) in a circumferential direction of the holder table 12.

The horizontal load detecting unit 120 is located on a supporting arm 121 to be in contact with a sideward surface of the holder table 12 on the −X side beside the holder table 12 in the X-axis direction, which is a direction to peel the protective tape T1. The supporting arm 121 is, as shown in FIG. 6, fixed by a lower part thereof to a sideward surface of the movable member 27 on the −X side and extends upward. Moreover, the supporting arm 121 is arranged to flank the horizontal load detecting unit 120 together with the holder table 12 from both sides in the X-axis direction by an upper and sideward surface thereof on the +X side.

The load sensors 111-113 and the horizontal load detecting unit 120 may be, for example, composed of piezoelectric devices, similarly to the vertical and horizontal load detecting units 41, 42 described in the first embodiment.

In the configuration where the horizontal load detecting unit 120 is provided, in place of the frame-fixing part 20 (see FIG. 1), a plurality of mechanical clamps that may be opened or closed by, for example, rotary cylinders, to nip the annular frame R may be arranged around the holder table 12. In this configuration, the horizontal load detecting unit 120 and the supporting arm 121 may be arranged not to be interfered by the mechanical clamps.

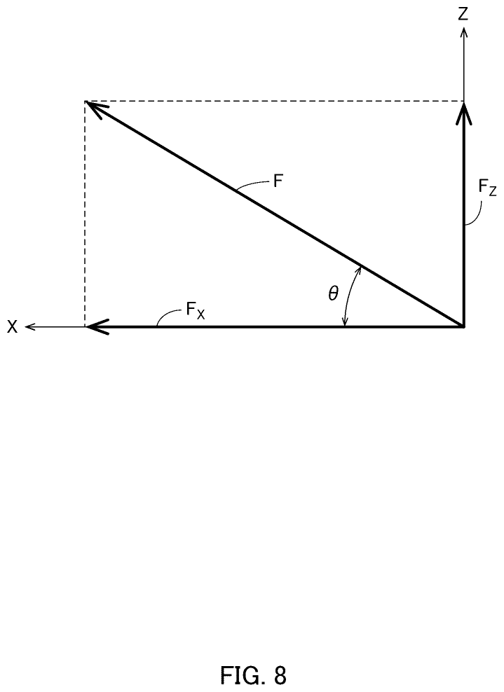

The vertical load detecting unit 110 may detect a sum of the loads from the three load sensors 111-113 while the protective tape T1 is being peeled as a vertical load value Fz (see FIG. 8). More specifically, while the protective tape T1 is being peeled, loads that tilt the holder table 12 with respect to a horizontal plane may be applied to the load sensors 111-113. Therefore, each of the load sensors 111-113 may detect both load in the upward direction (+Z direction) and load in the downward direction (−Z direction). In other words, the three load sensors 111-113 located between the supporting portions 29 and the movable member 27 are arranged in a state where compressive pressure is applied thereto, and thereby enabled to measure the load in the +Z direction and the load in the −Z direction. While the protective tape T1 is being peeled, a force to tilt the holder table 12 in the X-axis direction is applied the thee load sensors 111-113; therefore, among the load sensors 111-113, some may detect the load in the +Z direction, while the other may detect the load in the −Z direction. Accordingly, the sum of the load values detected by all of the three load sensors 111-113 are determined to be the load value Fz in the vertical direction while the protective tape T1 is being peeled.

The horizontal load detecting unit 120 is urged by the sideward surface of the holder table 12 on the −X side while the protective tape T1 is being peeled, and the load value detected by the horizontal load detecting unit 120 is determined to be a horizontal load value Fx (see FIG. 8). Optionally, the horizontal load detecting unit 120 may be located on a sideward surface of the holder table 12 on the +X side being the opposite side in FIG. 6, and the load value (Fx) detected by the horizontal load detecting unit 120 in such a location may be detected as a negative value.

According to the fifth embodiment, the vertical and horizontal load detecting units 110, 120 detect the tensile loads acting on the protective tape T1 being peeled periodically at predetermined intervals and output the detection signals corresponding to the horizontal load and the horizontal load to the controller 90.

While the protective tape T1 is being peeled, similarly to the first embodiment, the controller 90 controls the first horizontal movement assembly 22 and the rotation driving unit 38 to maintain the interior angle at the optimal value set by the interior angle setting unit 88 based on the detection signals being input.

The controller 90 may, as shown in FIG. 8, calculate the interior angle θ of the tensile force F acting on the protective tape T1 with respect to the horizontal direction (X direction) based on the detected vertical load value Fz and the detected horizontal load value Fx. With reference to FIG. 8, the interior angle θ may be calculated by a formula: θ=tan⁻¹(Fx/Fz). The interior angle θ calculated by the formula may be applied by the controller 90 to the actual interior angle θ of the protective tape T1 being peeled.

### Sixth Embodiment

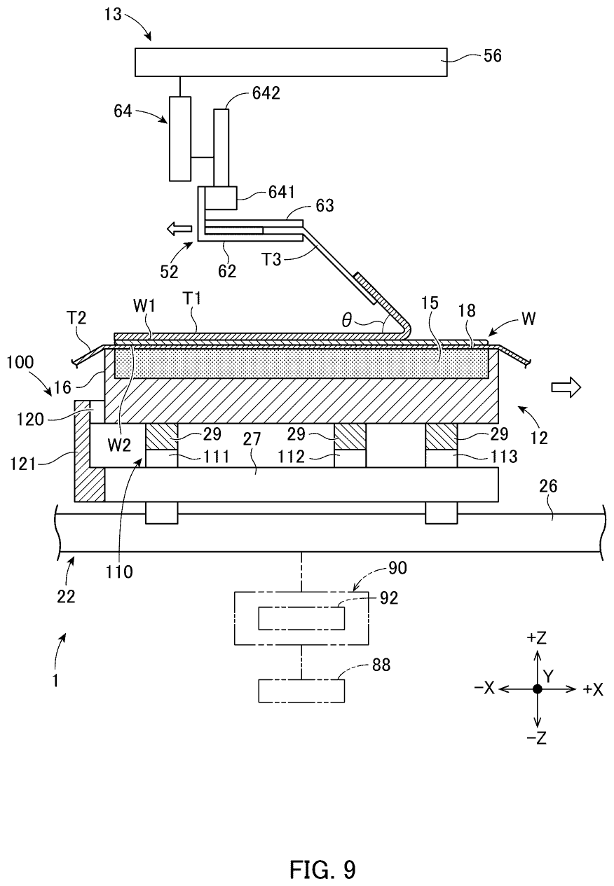

With reference to FIG. 9, a sixth embodiment of the present disclosure will be described. FIG. 9 is a schematic cross-sectional partial view, similarly to FIG. 3, of the peeling apparatus according to the sixth embodiment of the present disclosure. As shown in FIG. 9, the sixth embodiment illustrates a peeling apparatus, which is similar to the peeling apparatus in the second embodiment but is provided with the tensile load measuring unit 100 in place of the tensile load measuring unit 402. The sixth embodiment illustrates the peeling apparatus, which is similar to the peeling apparatus in the second embodiment but is provided with the tensile load measuring unit 100 (the vertical load detecting unit 110 and the horizontal load detecting unit 120) as described in the fifth embodiment around the holder table 12.

In the sixth embodiment, based on the detection signals from the vertical load detecting unit 110 and the horizontal load detecting unit 120 while the protective tape T1 is being peeled, the controller 90 controls, similarly to the second embodiment, the first and second horizontal movement assemblies 22, 56 and the clamp lift/lower assembly 64 to maintain the interior angle at the optimal value set by the interior angle setting unit 88.

### Seventh Embodiment

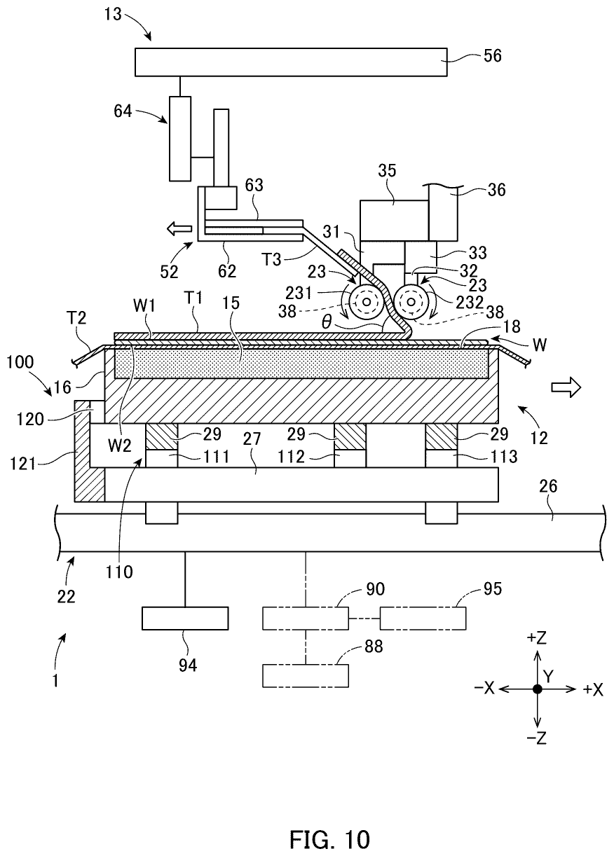

With reference to FIG. 10, a seventh embodiment of the present disclosure will be described. FIG. 10 is a schematic cross-sectional partial view, similarly to FIG. 4, of the peeling apparatus according to the seventh embodiment of the present disclosure. As shown in FIG. 10, the seventh embodiment illustrates a peeling apparatus, which is similar to the peeling apparatus in the third embodiment but is provided with the tensile load measuring unit 100 in place of the tensile load measuring unit 40. The seventh embodiment illustrates the peeling apparatus, which is similar to the peeling apparatus in the third embodiment but is provided with the tensile load measuring unit 100 (the vertical load detecting unit 110 and the horizontal load detecting unit 120) as described in the fifth embodiment around the holder table 12.

In the seventh embodiment, similarly to the third embodiment, the controller 90 controls the rotation driving unit 38 to maintain the optimal interior angle θ at the optimal value set by the interior angle setting unit 88.

### Eighth Embodiment

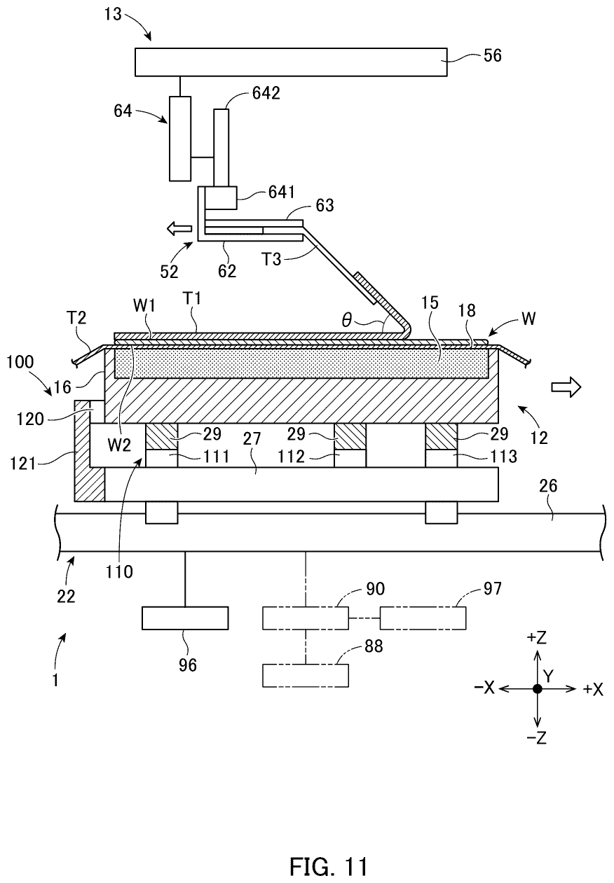

With reference to FIG. 11, an eighth embodiment of the present disclosure will be described. FIG. 11 is a schematic cross-sectional partial view, similarly to FIG. 5, of the peeling apparatus according to the eighth embodiment of the present disclosure. As shown in FIG. 11, the eighth embodiment illustrates a peeling apparatus, which is similar to the peeling apparatus in the fourth embodiment but is provided with the tensile load measuring unit 100 in place of the tensile load measuring unit 402. The eighth embodiment illustrates the peeling apparatus, which is similar to the peeling apparatus in the fourth embodiment but is provided with the tensile load measuring unit 100 (the vertical load detecting unit 110 and the horizontal load detecting unit 120) as described in the fifth embodiment around the holder table 12.

In the eighth embodiment, the controller 90 controls the clamp lift/lower assembly 64 to maintain the interior angle θ at the optimal value set by the interior angle setting unit 88.

As described above, according to the second through eighth embodiments, under the control of the controller 90, the interior angle θ between the protective tape T1 adhered to the surface W1 on the one side of the plate-formed workpiece W and the protective tape T1 peeled from the surface W1 may be maintained to be the interior angle θ at the optimal value. Thereby, the bending angle of the protective tape T1 during the peeling may be prevented from changing, and the plate-formed workpiece W may be prevented from cracking or adherence of the glue thereon.

It is noted that embodiments of the present disclosure may not necessarily be limited to the configurations described above but may be modified in various ways. The dimensions and the forms of any items in the embodiments described above may not necessarily be limited to those illustrated in the accompanying drawings but may be modified within the scope where the effects of the present invention are deliverable. Moreover, the embodiments may be modified as long as they do not depart from the scope of the object of the present invention.

For example, the first, third, fifth, and seventh embodiment are the examples where the protective tape T1 is peeled off without moving the two rollers 23; however, the protective tape T1 may be peeled by providing an additional horizontal movement assembly that may move the two rollers 23 and by moving the two rollers 23 in the −X direction. As such, the two rollers 23 and the holder table 12 may be moved in the X-axis direction (horizontal direction) relatively.

For another example, the protective tape T1 may not necessarily be peeled by the first and second horizontal movement assemblies 22, 56 moving the clamp 52 and the holder table 12, respectively, as illustrated in the second, fourth, sixth, or eighth embodiment. For example, the protective tape T1 may be peeled by moving at least one of the clamp 52 or the holder table 12 in the X-axis direction. As such, the clamp 52 and the holder table 12 may be moved in the X-axis direction (horizontal direction) relatively.

For another example, the tensile load measuring units 40, 402, 100 illustrated in the third, fourth, seventh, and eighth embodiments, respectively, may optionally be omitted.

As described above, the present disclosure is effective in controlling to maintain the interior angle between the protective tape being peeled and the protective tape remaining adhered, and thereby preventing the plate-formed workpiece from cracking or adherence of glue thereon.

What is claimed is:

1. A peeling apparatus configured to peel a protective member protecting a first surface on one side of a plate-formed workpiece from the first surface, comprising:
a holder table having a holder surface configured to hold a second surface of the plate- formed workpiece on the other side opposite to the first side; and
a peeling assembly configured to peel the protective member covering the first surface of the plate-formed workpiece held on the holder table,
wherein the peeling assembly includes:
a gripping unit configured to grip the protective member;
a horizontal movement assembly configured to move the gripping unit and the holder table relatively to each other linearly in a horizontal direction;
a separating assembly configured to separate the gripping unit gripping the protective member from the holder table;
an interior angle setting unit configured to set an interior angle between the protective member adhered to the first surface of the plate-formed workpiece and the protective member being peeled; and
a controller configured to maintain the interior angle at an angle set by the interior angle setting unit while the protective member is being peeled.

2. The peeling apparatus according to claim 1,
wherein the gripping unit is composed of two rollers,
wherein the separating assembly is composed of a rotation driving unit configured to rotate the two rollers relatively to each other,
wherein the peeling assembly further includes:
a horizontal load detecting unit configured to detect a tensile load in the horizontal direction; and
a vertical load detecting unit configured to detect a tensile load in a vertical direction,
wherein the controller includes a ratio calculating unit configured to calculate a ratio between the tensile load in the horizontal direction and the tensile load in the vertical direction for forming the interior angle set by the interior angle setting unit with the protective member, and
wherein the controller is configured to control the horizontal movement assembly and the separating assembly to equate a ratio between the tensile load in the horizontal direction detected by the horizontal load detecting unit and the tensile load in the vertical direction detected by the vertical load detecting unit with the ratio calculated by the ratio calculating unit.

3. The peeling apparatus according to claim 1,
wherein the gripping unit is composed of a clamp configured to grip an outer peripheral portion of the protective member,
wherein the separating assembly is composed of a clamp lift/lower assembly configured to lift the clamp,
wherein the peeling assembly further includes:
a horizontal load detecting unit configured to detect a tensile load in the horizontal direction; and
a vertical load detecting unit configured to detect a tensile load in a vertical direction,
wherein the controller includes a ratio calculating unit configured to calculate a ratio between the tensile load in the horizontal direction and the tensile load in the vertical direction for forming the interior angle set by the interior angle setting unit with the protective member, and
wherein the controller is configured to control the horizontal movement assembly and the separating assembly to equate a ratio between the tensile load in the horizontal direction detected by the horizontal load detecting unit and the tensile load in the vertical direction detected by the vertical load detecting unit with the ratio calculated by the ratio calculating unit.

4. The peeling apparatus according to claim 1,
wherein the gripping unit is composed of two rollers,
wherein the separating assembly is composed of a rotation driving unit configured to rotate the two rollers relatively to each other,
wherein the peeling assembly further includes:
a horizontal position detecting unit configured to detect relative positions of the gripping unit and the holder table in the horizontal direction; and
a data table defining rotation speeds of the rotation driving unit corresponding to the relative positions of the gripping unit and the holder table in the horizontal direction,
wherein the controller is configured to
control the horizontal movement assembly to move the gripping unit and the holder table relatively to each other at a constant speed, and
control a rotation speed of the rotation driving unit based on the relative positions of the gripping unit and the holder table in the horizontal direction detected by the horizontal position detecting unit with reference to the data table.

5. The peeling apparatus according to claim 1,
wherein the gripping unit is composed of a clamp configured to grip an outer peripheral portion of the protective member,
wherein the separating assembly is composed of a clamp lift/lower assembly configured to lift the clamp,
wherein the peeling assembly further includes:
a horizontal position detecting unit configured to detect relative positions of the gripping unit and the holder table in the horizontal direction; and
a data table defining ascending speeds of the clamp lift/lower assembly corresponding to the relative positions of the gripping unit and the holder table in the horizontal direction,
wherein the controller is configured to
control the horizontal movement assembly to move the gripping unit and the holder table relatively to each other at a constant speed, and
control an ascending speed of the clamp lift/lower assembly based on the relative positions of the gripping unit and the holder table in the horizontal direction detected by the horizontal position detecting unit with reference to the data table.

6. The peeling apparatus according to claim 2,
wherein the vertical load detecting unit is located below the holder table to support the holder table, and
wherein the horizontal load detecting unit is located beside the holder table in a peeling direction to peel the protective member.

7. The peeling apparatus according to claim 3,
wherein the vertical load detecting unit is located below the holder table to support the holder table, and
wherein the horizontal load detecting unit is located beside the holder table in a direction to peel the protective member.

8. A peeling method for peeling a protective member protecting a first surface on one side of a plate-formed workpiece from the first surface, comprising:
a holding process to hold a second surface of the plate-formed workpiece on the other side opposite to the first side;
a gripping process to grip the protective member by a gripping unit; and
a peeling process to peel the protective member by moving the gripping unit and the holder table relatively to each other linearly in a horizontal direction and separating the gripping unit gripping the protective member from the holder table while maintaining an interior angle between the protective member adhered to the first surface of the plate-formed workpiece and the protective member being peeled from the first surface of the plate-formed workpiece at preset angle.
